(19) United States
(12) Patent Application Publication
(10) Pub. No.: US 2026/0359536 A1
(43) Pub. Date: Nov. 12, 2026

(54) DESIGN-BASED SAMPLING FOR EXAMINATION OF SEMICONDUCTOR SPECIMENS

(71) Applicant: Applied Materials Israel Ltd., Rehovot (IL)

(72) Inventors: Bar DUBOVSKI, Rehovot (IL); Ran YACOBY, Rehovot (IL); Nitin MANWARE, Pune (IN); Aviram SINVANI, Rehovot (IL); Itamar RAIN, Rehovot (IL)

(21) Appl. No.: 19/205,895

(22) Filed: May 12, 2025

(51) Int. Cl. G06F 30/333; G06N 20/00

(52) U.S. Cl. CPC G06F 30/333; G06N 20/00

(57) ABSTRACT

There is provided a system and method of generating a training set during setup, and runtime monitoring design patterns in semiconductor specimens. The setup phase includes obtaining a set of design clips representing design patterns, grouping the clips into bins based on one or more periodicity characteristics, and, for each bin, extracting feature vectors and clustering the clips into clusters. For each cluster, a subset of design clips that spans a comprehensive range of unique design pattern variations is sampled to form a training set. The runtime phase includes monitoring new design clips during runtime by assigning each new clip to a bin and cluster, extracting its feature vector, and computing an anomaly score based on its distance to the cluster center. This anomaly score indicates the degree of deviation from representative patterns and triggers appropriate actions, thereby enhancing defect detection and process monitoring in semiconductor manufacturing.

### TECHNICAL FIELD

The presently disclosed subject matter relates, in general, to the field of examination of a semiconductor specimen, and more specifically, to design-based clustering and sampling for semiconductor specimen examination.

### BACKGROUND

Current demands for high density and performance associated with ultra large-scale integration of fabricated devices require nanometer-scale features, increased transistor and circuit speeds, and improved reliability. With increasing miniaturization and complexity of semiconductor designs, the dimensions of device features, often referred to as critical dimensions, are continuously decreasing. Such demands require the formation of device features with high precision and uniformity, which, in turn, necessitates careful monitoring and accurate control throughout the fabrication process, including automated examination of the devices while they are still in the form of semiconductor wafers.

Semiconductor devices are fabricated through multiple processes, including photolithography, etching, deposition, planarization, and implantation, etc., to define precise patterns and structures on semiconductor wafers. To ensure the quality and reliability of the final semiconductor devices, examination steps may be conducted repeatedly throughout the manufacturing process, for example following specific processing steps, after forming particular layers, or at other designated manufacturing stages. Moreover, each examination step itself may be repeated multiple times, either across different wafer locations or at the same wafer location using various inspection settings and conditions.

Automated wafer inspection techniques commonly utilize imaging technologies, such as optical microscopy or scanning electron microscopy (SEM), to acquire high-resolution images of the wafer surface. These acquired images are subsequently analyzed using computational methods to detect and classify potential defects, abnormalities, or process deviations.

Alongside these imaging-based inspection methods, semiconductor fabrication extensively utilizes abstract design data, such as computer-aided design (CAD) data, which defines the intended geometrical patterns of integrated circuits. CAD data provides detailed information on the intended device layout, specifying positions, shapes, and dimensions of design elements. These design data sets are typically structured as polygonal patterns or vector-based representations of the device layout. In some cases, design data can significantly facilitate automated inspection tasks, including defect detection and process monitoring. Employing CAD data in wafer examination can yield substantial advantages, such as accelerated analysis times, improved defect detection sensitivity, and reduced dependency on manual inspections.

Recent advancements in computational processing power have enabled the increasing use of machine learning (ML) technologies to assist the automated examination process so as to improve overall manufacturing yields. For instance, ML models can be trained to leverage abstract design data to perform various inspection-related tasks, such as predicting or simulating expected inspection images. To effectively train these ML models, the availability of representative and diverse datasets derived from CAD-based information is essential.

### SUMMARY

In accordance with certain aspects of the presently disclosed subject matter, there is provided a computerized method of generating a training set for training a machine learning (ML) model, the method comprising: obtaining a set of design clips representing a set of design patterns of a semiconductor specimen; grouping the set of design clips into a plurality of bins based on one or more periodicity characteristics of the set of design patterns; for each bin of the plurality of bins: extracting feature vectors representing design patterns of design clips in the bin, and clustering the design clips to one or more clusters based on the feature vectors thereof; and for each cluster, sampling a subset of design clips that collectively span a full spectrum of unique design pattern variations present within the cluster, giving rise to one or more subsets of design clips corresponding to the one or more clusters in the bin; wherein the one or more subsets of design clips for each bin of the plurality of bins constitute a training set for training the ML model.

In addition to the above features, the method according to this aspect of the presently disclosed subject matter can comprise one or more of features (i) to (xii) listed below, in any desired combination or permutation which is technically possible:
(i). The set of design clips corresponds to a set of locations of interest on the semiconductor specimen resulting from a preceding inspection process.
(ii). The one or more periodicity characteristics of the design patterns indicates periodic repetition of design elements along one or more directions of the X axis, Y axis, both X and Y axes, an oblique direction relative to X or Y axis, or absence of periodic repetition in any direction.
(iii). The extracted feature vectors are of a type selected from a group comprising Fourier features, histogram of moments, histogram of oriented gradients (HOG), vertex-related function, and unique polygon counts.
(iv). The clustering is performed using a clustering algorithm selected from a group comprising: K-means clustering, Gaussian Mixture Models (GMM), Dirichlet Process GMM (DPGMM), and Hierarchical Density-Based Spatial Clustering of Applications with Noise (HDBSCAN).
(v). The clustering is performed in a plurality of stages, with each stage applying a designated clustering algorithm to one or more resulting clusters from a preceding stage.
(vi). The sampling comprises ranking design clips in the cluster, and selecting, from among the ranked design clips, a subset of design clips.
(vii). The sampling comprises ranking design clips in the cluster with respect to the center of the cluster, and selecting, from among the ranked design clips, a subset of design clips that is evenly distributed across a feature space of the cluster.
(viii). The method further comprises, prior to the sampling, performing first duplicate removal within each cluster to eliminate design clips with duplicate design patterns. In such cases, the sampling, such as the ranking of the design clips in the cluster, can be performed on the remaining design clips after the first duplicate removal.
(ix). The method further comprises performing second duplicate removal across the sampled one or more subsets of design clips within each bin.
(x). The method further comprises selecting one or more design clips from the sampled one or more subsets of design clips for each bin; registering the one or more design clips with one or more corresponding images to form one or more registered pairs of design clips and images; including the one or more registered pairs of design clips and images in the training set; and incorporating remaining design clips from the sampled one or more subsets of design clips and corresponding images directly into the training set without registration.
(xi). The selection of the one or more design clips is based on diversity ranking in accordance with a predefined budget.
(xii). The training set is used to train the ML model configured to perform image simulation based on design data.

In accordance with other aspects of the presently disclosed subject matter, there is provided a computerized system for runtime monitoring of design patterns in a semiconductor specimen, the system comprising a processing circuitry configured to obtain, during runtime, a new design clip representing a design pattern of the semiconductor specimen; assign the new design clip into one bin of a plurality of bins based on one or more periodicity characteristics of the design pattern; extract a feature vector representing the design pattern; assign the new design clip to a cluster of one or more clusters in the bin based on the feature vector; and compute an anomaly score for the new design clip based on a distance between the feature vector and a center of the cluster, wherein the anomaly score is indicative of a degree of deviation of the new design clip from a set of representative design clips previously included in a training set during a setup phase.

This aspect of the disclosed subject matter can comprise one or more of features (i) to (xii) listed above with respect to the method, mutatis mutandis, in any desired combination or permutation which is technically possible. In addition to or in lieu of the above features, this aspect can comprise one or more of features (xiii) to (xviii) listed below, in any desired combination or permutation which is technically possible:
(xiii). The processing circuitry is further configured to generate an alert if the anomaly score exceeds a predetermined threshold, thereby indicating that the design pattern in the new design clip is insufficiently represented in the training set.
(xiv). The training set is updated to include the new design clip and a corresponding image, and the updated training set is usable to re-train a machine learning (ML) model which is previously trained for image simulation during the setup phase using the training set.
(xv). The processing circuitry is further configured to instruct the examination tool to acquire an actual image instead of performing image simulation based on the new design clip using a machine learning (ML) model previously trained during the setup phase using the training set.
(xvi). In cases where the anomaly score does not exceed a predetermined threshold, the processing circuitry is further configured to process the new design clip using a machine learning (ML) model, to generate a simulated image, wherein the ML model is previously trained for image simulation during the setup phase using the training set.
(xvii). The plurality of bins is generated during the setup phase. The one or more periodicity characteristics indicate periodic repetition of design elements along one or more directions of the X axis, Y axis, both X and Y axes, an oblique direction relative to X or Y axis, or absence of periodic repetition in any direction.
(xviii). The one or more clusters and one or more cluster centers thereof in each bin are generated during the setup phase. The new design clip is assigned by comparing the feature vector to the one or more cluster centers of the one or more clusters, and assigning the new design clip to the cluster whose cluster center is closest to the feature vector.

In accordance with other aspects of the presently disclosed subject matter, there is provided a non-transitory computer-readable medium comprising instructions that, when executed by a computer, cause the computer to perform a method of runtime monitoring of design patterns in a semiconductor specimen, the method comprising: obtaining, during runtime, a new design clip representing a design pattern of the semiconductor specimen; assigning the new design clip into one bin of a plurality of bins based on one or more periodicity characteristics of the design pattern; extracting a feature vector representing the design pattern; assigning the new design clip to a cluster of one or more clusters in the bin based on the feature vector; and computing an anomaly score for the new design clip based on a distance between the feature vector and a center of the cluster, wherein the anomaly score is indicative of a degree of deviation of the new design clip from a set of representative design clips previously included in a training set during a setup phase.

This aspect of the disclosed subject matter can comprise one or more of features (i) to (xviii) listed above, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of design data sampling for generating a training set for training a machine learning (ML) model in accordance with certain embodiments of the presently disclosed subject matter.

FIG. 3 illustrates a generalized flowchart of further selection and registration in accordance with certain embodiments of the presently disclosed subject matter.

FIG. 4 illustrates a generalized flowchart of a runtime monitoring process of design patterns in accordance with certain embodiments of the presently disclosed subject matter.

FIG. 5 illustrates examples of four different types of periodicity characteristics in accordance with certain embodiments of the presently disclosed subject matter.

FIG. 6 illustrates an example of a cropped design clip and an uncropped design clip in accordance with certain embodiments of the presently disclosed subject matter.

FIG. 7 shows a schematic illustration of the supervised training phase for the ML model in accordance with certain embodiments of the presently disclosed subject matter.

FIG. 8 illustrates an example of an elbow plot in accordance with certain embodiments of the presently disclosed subject matter.

FIG. 9 illustrates an example of a new design clip and its anomaly determination in accordance with certain embodiments of the presently disclosed subject matter.

FIG. 10 illustrates an example of a diversity ranking process in accordance with certain embodiments of the presently disclosed subject matter.

### DETAILED DESCRIPTION OF EMBODIMENTS

Design data, such as computer-aided design (CAD) representations, are increasingly utilized to facilitate examination tasks in semiconductor manufacturing. These design data provide precise representations of the intended layout of integrated circuits, specifying the shapes, dimensions, and spatial arrangements of device features. Such data sets typically include polygonal patterns or vector-based geometries reflecting design layouts, and can be effectively leveraged for various examination tasks, such as defect-related examination (e.g., defect detection, defect review, and defect classification, etc.), and/or metrology-related examination (e.g., critical dimension (CD) measurements, and overlay, etc.).

By way of example, automated wafer inspection processes in semiconductor manufacturing typically produce a vast number of candidate defect locations, especially when inspecting advanced semiconductor devices with nanometer-scale features. The sheer volume of defect candidate data makes direct manual review impractical and computationally costly. Consequently, there is a critical need to efficiently group and analyze these candidate locations by leveraging the inherent design information contained in the CAD data. Grouping defect candidates based on their underlying design patterns can help reveal which specific patterns are more prone to defectivity, thereby enabling targeted process optimization and more effective allocation of inspection resources.

In addition, semiconductor manufacturers frequently use machine learning (ML) models trained on design data for tasks such as defect detection, process control, and image simulation, etc. Training these ML models effectively requires a carefully curated and balanced dataset across the full spectrum of design patterns present on a specimen. However, traditional sampling approaches often rely on either manual selection of candidate locations or generic clustering methods that often fail to achieve uniformity and capture the diversity of patterns. These approaches tend to over-represent common patterns and overlook infrequent, yet potentially critical, design features. Such imbalanced datasets degrade the ability of ML models to generalize reliably, causing poor performance when encountering uncommon or novel patterns.

Moreover, once an ML model is trained, new design patterns encountered during production may exhibit previously unseen features, leading to inference errors and degraded performance. Currently, there is no effective mechanism to continuously monitor for such novel patterns in runtime.

Consequently, these challenges underscore a need for robust and systematic sampling methods that organize large sets of design patterns and select a representative, diverse subset of design clips for ML training. Additionally, there is a need for a runtime monitoring mechanism that can determine when the new design data significantly deviate from the representative patterns in the training set—thereby triggering alerts or prompting the acquisition of additional data for retraining the ML model.

Accordingly, certain embodiments of the presently disclosed subject matter propose a design-based sampling system, which does not have one or more of the disadvantages described above. In certain embodiments of the present disclosure, design data is organized by grouping design clips into bins based on their periodicity characteristics, followed by clustering within the bins, and applying diversity-based sampling to derive a representative training set for machine learning model training. In addition, a runtime mechanism assigns new design clips to the pre-established clusters and computes an anomaly score, thereby enabling prompt alerts and/or data updates when novel patterns are detected, as will be detailed below.

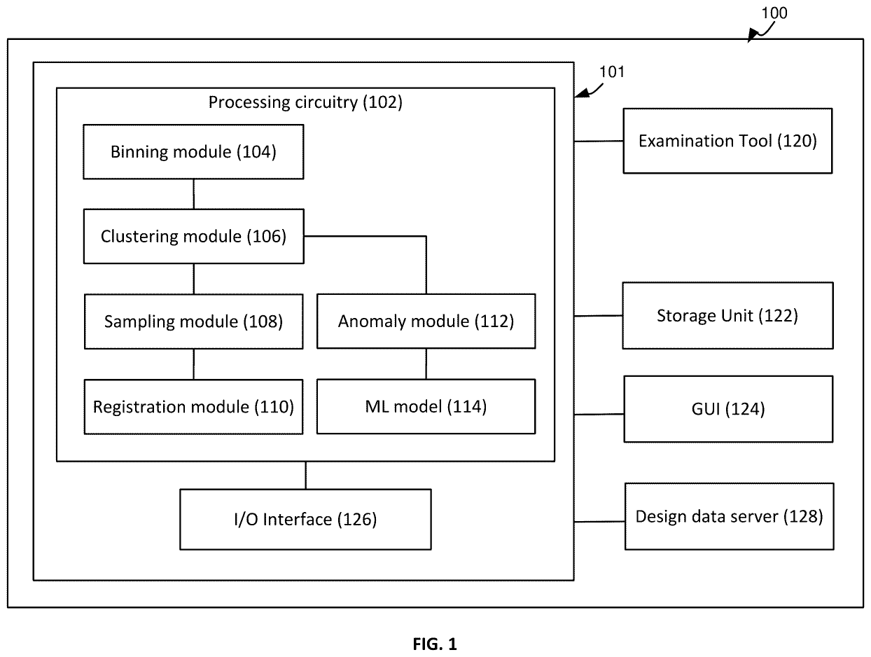

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, nuisance filtration, segmentation, and/or metrology operations, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

The one or more examination tools 120 can include one or more inspection tools and/or one or more review tools. In some cases, an inspection tool can be configured to scan a specimen (e.g., an entire wafer, an entire die, or portions thereof) to capture inspection images (typically, at a relatively high speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer, and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool can be configured to capture review images of at least some of the defect candidates detected by inspection tools for ascertaining whether a defect candidate is indeed a defect of interest (DOI). Such a review tool is usually configured to inspect fragments of a specimen, one at a time (typically, at a relatively low speed and/or high-resolution). By way of example, the review tool can be an electron beam tool, such as, e.g., a scanning electron microscope (SEM), etc. An SEM is a type of electron microscope that produces images of a specimen by scanning the specimen with a focused beam of electrons. The electrons interact with atoms in the specimen, producing various signals that contain information on the surface topography and/or composition of the specimen. An SEM is capable of accurately inspecting and measuring features during the manufacture of semiconductor wafers.

In some embodiments of the present disclosure, at least one of the examination tools 120 has metrology capabilities and can be configured to capture images and perform metrology operations on the captured images. Such an examination tool is also referred to as a metrology tool. One example of a metrology tool used within the examination system is a Critical Dimension Scanning Electron Microscope (CD-SEM). CD-SEM is a specialized tool designed to capture high-resolution images of semiconductor structures and perform metrology operations on those structures. The CD-SEM can be used to obtain precise dimensional measurements, such as critical dimension (CD) or overlay measurements, with respect to certain structural features on the specimen, to determine whether they meet the design specifications.

The various examination tools can be different tools located at the same or at different locations, or integrated as a single tool operated in different modes. In some cases, the same examination tool can provide low-resolution image data and high-resolution image data. The resulting image data (low-resolution image data and/or high-resolution image data) can be transmitted—directly or via one or more intermediate systems—to system 101. The present disclosure is not limited to any specific type of examination tools and/or the resolution of image data resulting from the examination tools.

According to certain embodiments of the presently disclosed subject matter, the examination system 100 comprises a computer-based system 101 operatively connected to the examination tool 120, and capable of performing design-based sampling for generating a training set during setup, or performing runtime monitoring of new design patterns. System 101 is thus also referred to as a design data sampling system (also referred to as CAD sampling system), or a runtime monitoring system.

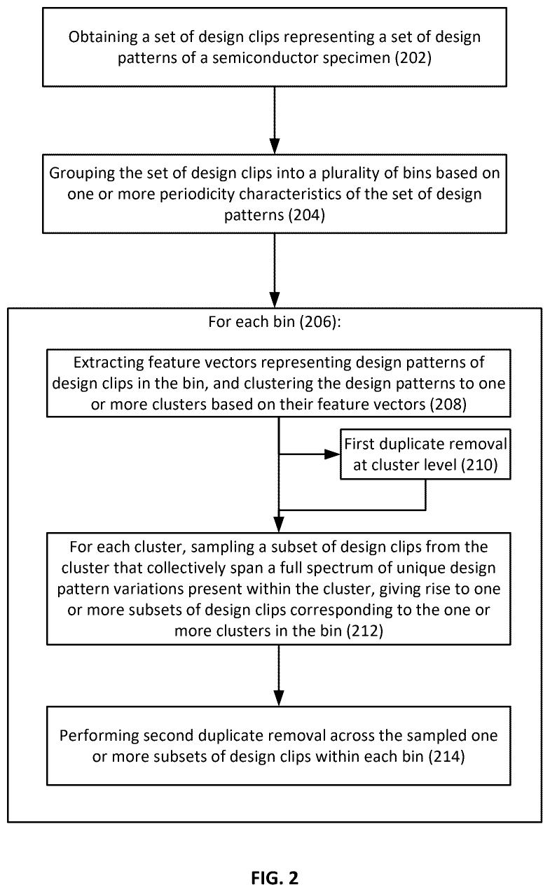

System 101 includes a processing circuitry 102 operatively connected to a hardware-based I/O interface 126 and configured to provide the processing necessary for operating the system, as further detailed with reference to FIGS. 2-4. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, system 101 can be configured as a design data sampling system capable of sampling design patterns and generating a representative training set during a setup phase. In such cases, one or more functional modules comprised in the processing circuitry 102 of system 101 can include a binning module 104, a clustering module 106, a sampling module 108, and, optionally, a registration module 110.

Specifically, the processing circuitry 102 can be configured to obtain, via an I/O interface 126, a set of design clips representing a set of design patterns of a semiconductor specimen. The binning module 104 can be configured to group the set of design clips into a plurality of bins based on one or more periodicity characteristics of the set of design patterns.

For each bin of the plurality of bins, the clustering module 106 can be configured to extract feature vectors representing design patterns of design clips in the bin, and cluster the design clips in the bin to one or more clusters based on the feature vectors thereof. The sampling module 108 can be configured to sample, for each cluster, a subset of design clips that collectively span/cover a full spectrum of unique design pattern variations present within the cluster, giving rise to one or more subsets of design clips corresponding to the one or more clusters in the bin. The one or more subsets of design clips for each bin of the plurality of bins collectively constitute a training set usable for training a ML model (such as the ML model 114 which has not been trained yet).

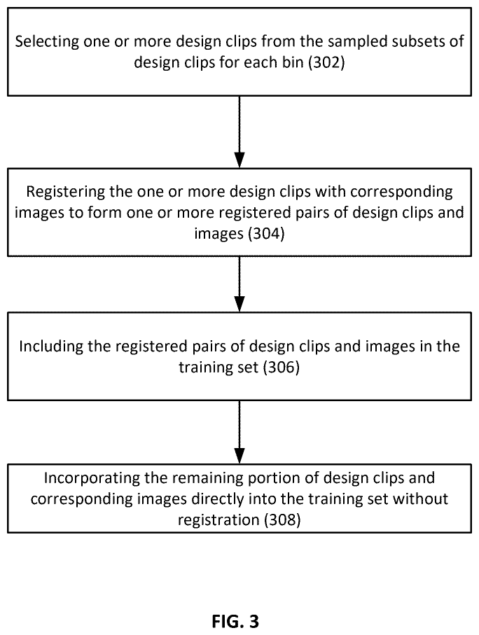

In some cases, optionally, the registration module 110 can be configured to select one or more design clips from the sampled one or more subsets of design clips for each cluster, and register the one or more design clips with one or more corresponding images to form one or more registered pairs of design clips and images. The registered pairs of design clips and images can be included in the training set, together with the remaining design clips and their images, which are incorporated without registration, as will be detailed below with reference to FIGS. 2 and 3. The training set, upon being generated, can be used to train the ML model 114, e.g., for design-based image simulation.

According to certain embodiments, in some cases, system 101 can be configured as a runtime monitoring system after the setup phase. In such cases, one or more functional modules comprised in the processing circuitry 102 of system 101 can comprise the binning module 104, the clustering module 106, an anomaly module 112, and a ML model 114 that was previously trained during the setup phase.

Specifically, the processing circuitry 102 can be configured to obtain, via an I/O interface 126, during runtime, a new design clip representing a design pattern of a semiconductor specimen. The binning module 104 can be configured to assign the new design clip into one bin of a plurality of bins based on one or more periodicity characteristics of the design pattern. The clustering module 106 can be configured to extract a feature vector representing the design pattern, and assign the new design clip to a cluster of one or more clusters in the bin based on the feature vector.

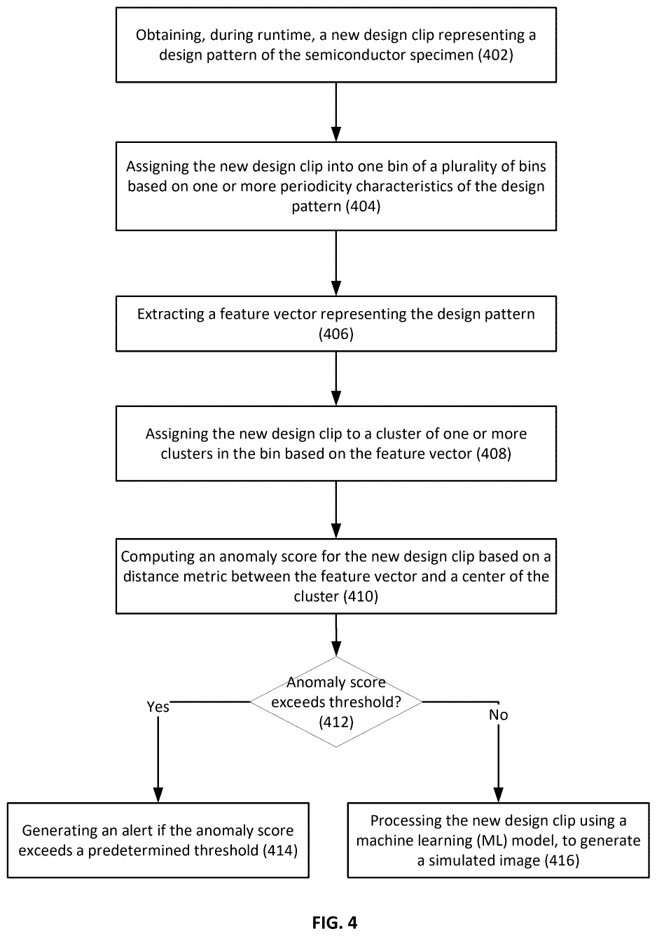

The anomaly module 112 can be configured to compute an anomaly score for the new design clip based on a distance between the feature vector and a center of the cluster. The anomaly score is indicative of a degree of deviation of the new design clip from a set of representative design clips included in a training set during the setup phase. In cases where the anomaly score does not exceed a predetermined threshold, the trained ML model 114 can be used to process the new design clip to generate a simulated image, as will be detailed below with reference to FIG. 4.

In some cases, the functional modules included in the runtime monitoring system can be regarded as part of an examination recipe usable for performing runtime monitoring and examination operations for semiconductor specimens to be examined.

According to certain embodiments, the ML model 114 can be implemented as various types of ML models, such as, e.g., decision tree, Support Vector Machine (SVM), Artificial Neural Network (ANN), regression model, transformer, Bayesian network, or ensembles/combinations thereof, etc. The learning algorithms used by the ML models can be any of the following: supervised learning, unsupervised learning, self-supervised, semi-supervised learning, or a combination thereof, etc. The presently disclosed subject matter is not limited to the specific types of ML models or the specific types of learning algorithms used by the ML models.

By way of example, in some cases, the ML model 114 can be implemented as a deep neural network (DNN). DNN can comprise multiple layers organized in accordance with the respective DNN architecture. By way of non-limiting example, the layers of DNN can be organized in accordance with the architecture of a Convolutional Neural Network (CNN), Recurrent Neural Network, Recursive Neural Networks, autoencoder, Generative Adversarial Network (GAN), or otherwise. Optionally, at least some of the layers can be organized into a plurality of DNN sub-networks. Each layer of DNN can include multiple basic computational elements (CEs), typically referred to in the art as dimensions, neurons, or nodes.

The weighting and/or threshold values associated with the CEs of a DNN and the connections thereof can be initially selected prior to training, and can be further iteratively adjusted or modified during training to achieve an optimal set of weighting and/or threshold values in a trained DNN. After each iteration, a difference can be determined between the actual output produced by the DNN module and the target output associated with the respective training set of data. The difference can be referred to as an error value. Training can be determined to be complete when a loss/cost function indicative of the error value is less than a predetermined value, or when a limited change in performance between iterations is achieved. A set of input data used to adjust the weights/thresholds of a DNN is referred to as a training set.

It is noted that the teachings of the presently disclosed subject matter are not bound by the specific architecture of the ML model as described above.

It is to be noted that while certain embodiments of the present disclosure refer to the processing circuitry 102 being configured to perform the above-recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules in the CAD sampling system, such as the grouping of design clips into bins, the clustering within each bin, and the sampling etc., and/or the operations of the various functional modules in the runtime monitoring system, such as the grouping and clustering of the new design clip, and the anomaly computation, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more additional examination modules, such as, e.g., defect detection, nuisance filtration module, Automatic Defect Review (ADR) module, Automatic Defect Classification (ADC) module, metrology operation module, and/or other examination modules which are usable for examination of a semiconductor specimen. The one or more examination modules can be implemented as stand-alone computers, or their functionalities (or at least part thereof) can be integrated with the examination tools 120. In some cases, the output of system 101, e.g., the training set during setup, and/or the anomaly score and the simulated image during runtime, can be provided to the one or more additional examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store the images and/or derivatives thereof produced by the examination tool 120, and/or the training set as described above. System 100 can also comprise a design data server 128 configured to store design data and design images derived therefrom. Accordingly, the input data as required can be retrieved from the storage unit 122 and design data server 128, and provided to the processing circuitry 102 for further processing. The output of system 101, such as, e.g., the training set during setup, and/or the anomaly score and the simulated image during runtime, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including the design data and/or images of the specimen, etc. The user may be provided, through the GUI, with options of defining certain operation parameters. The user may also view at least some of the operation results or intermediate processing results, such as, e.g., the bins, clusters, and/or the training set during setup, and/or the binning and clustering of the new design clip, the anomaly score and the simulated image during runtime, etc., on the GUI.

In some cases, system 101 can be further configured to send, via I/O interface 126, the operation results to the examination tools 120 for further processing. In some cases, system 101 can be further configured to send the results to external systems (e.g., Yield Management System (YMS) of a fabrication plant (fab)). A yield management system (YMS) in the context of semiconductor manufacturing is a data management, analysis, and tool system that collects data from the fab, especially during manufacturing ramp-ups, and helps engineers find ways to improve yield. A YMS helps semiconductor manufacturers and fabs manage high volumes of production analysis with fewer engineers. These systems analyze the yield data and generate reports. A YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tools 120 and the system 101 can be located at the same entity (in some cases hosted by the same device) or distributed over different entities. By way of another example, as described above, in some cases system 101 can be configured as a CAD sampling system during setup, while in some other cases, system 101 can be configured as a runtime monitoring system. The setup system and the runtime system can be located at the same entity (in some cases hosted by the same device), or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of the examination tools 120, storage unit 122, design data server 128 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools in examination-related processes.

While not necessarily so, the process of operations of systems 101 and 100 can correspond to some or all of the stages of the methods described with respect to FIGS. 2-4. Likewise, the methods described with respect to FIGS. 2-4 and their possible implementations can be implemented by systems 101 and 100. It is therefore noted that embodiments discussed in relation to the methods described with respect to FIGS. 2-4 can also be implemented, mutatis mutandis, as various embodiments of the systems 101 and 100, and vice versa.

As described above, a semiconductor specimen is typically made of multiple layers. The examination process of a specimen can be performed a multiplicity of times during the fabrication process of the specimen, for example following certain processing steps of specific layers. For the purpose of illustration only, certain embodiments of the following description are described with respect to CAD sampling for one or more specific layers of the specimen. Those skilled in the art will readily appreciate that the teachings of the presently disclosed subject matter can be performed for any layer of the specimen. The present disclosure should not be limited to the number of layers comprised in the specimen and/or the specific layer(s) to be examined.

Referring to FIG. 2, there is illustrated a generalized flowchart of design data sampling for generating a training set for training a machine learning (ML) model in accordance with certain embodiments of the presently disclosed subject matter.

Initially, a set of design clips can be obtained (202) (e.g., by the binning module 104 of the processing circuitry 102 when system 101 is configured as a CAD sampling system), representing a set of design patterns of a semiconductor specimen.

Each design clip represents a specific design pattern extracted from the overall design data of the semiconductor specimen. The overall design data represents the intended geometrical layout of device features on the specimen, specifying positions, shapes, and dimensions of design elements. Design data can be represented in various formats, such as, e.g., in the format of computer-aided design (CAD) layouts. By way of example, CAD design data can be represented as a set of polygons that describe the geometrical layout of device features. In some cases, this design data can be stored in text-based file formats (such as, e.g., GDSII files when exported in a human-readable form or similar formats) that list the coordinates or vertices of the polygons. This text-based representation allows for easier parsing and processing of the design layout information for purposes such as sampling.

In some embodiments, the set of design clips can correspond to a set of locations of interest on the specimen resulting from a preceding inspection process. For instance, the set of locations of interest can represent a set of defect candidate locations that have been identified from a defect map. The defect map can be generated by an automated defect detection process, wherein the candidate locations correspond to locations/areas with a higher probability of defect presence.

The set of design clips can be cropped from the overall design data of the specimen. By way of example, the relevant portions of the design data can be extracted/cropped at locations corresponding to the set of locations of interest. This extraction isolates the specific design patterns associated with potential defect sites, forming the raw input for subsequent processing steps in the sampling system.

The set of design clips, once obtained, can be grouped (204) (e.g., by the binning module 104) into a plurality of bins based on one or more periodicity characteristics of the set of design patterns.

The periodicity characteristics reflect whether a design clip exhibits periodic repetition of design elements/structures along one or more directions in the plane. By way of example, the one or more periodicity characteristics of the design patterns may indicate periodic repetition of design elements along one or more directions of the X axis, Y axis, both X and Y axes, any oblique direction relative to X or Y axis, or absence of periodic repetition in any direction.

In some cases, to facilitate periodicity analysis, rasterized versions of the design patterns may be generated from the polygon-based representation in CAD data. For instance, each unique polygon in the CAD data can be labeled by the coordinates of its vertices, with the first (top-left) vertex set as the origin. The polygons in CAD can then be projected or rendered onto a 2D pixel grid. This rasterization effectively converts the abstract, polygon-based geometry into an image-like format, enabling the use of image-processing techniques for further processing. Once rasterized, the design clip can be visually analyzed to detect and/or measure periodic structures.

When assessing periodicity, each CAD layer can be considered “periodic” along a direction of a certain axis (for example, x or y) if every unique polygon in that layer appears repeatedly at consistent intervals along that axis. A design clip (sometimes referred to as a “site”) is deemed periodic if it is found to be periodic in every layer within that clip.

By way of example, in some cases, the spatial arrangement of polygons can be examined row-by-row (for the x-axis) or column-by-column (for the y-axis), where close rows (or columns) can be grouped if they differ by only a small threshold. Within each row, the system inspects the distances between adjacent polygons to see if these distances repeat with a certain period. A design clip with only one instance of a unique polygon is generally considered non-periodic.

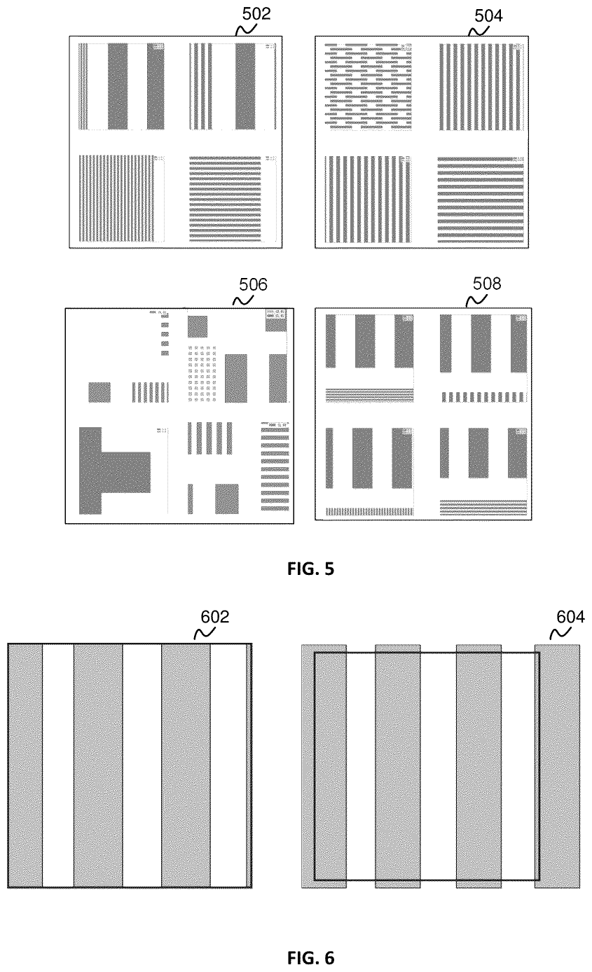

FIG. 5 provides examples of four different types of periodicity characteristics in accordance with certain embodiments of the presently disclosed subject matter. In these examples, the rasterized versions of design patterns are shown in four sub-figures marked as 502, 504, 506, and 508.

Sub-figure 502 demonstrates four patterns that are periodic along the Y axis only. Visually, one can see vertical stripes (or horizontal strips in the last pattern) repeated consistently in the Y direction. Sub-figure 504 illustrates four patterns that are periodic along both the X and Y axes. For instance, the grid-like arrangement of stripes in the first pattern repeats both vertically and horizontally. Sub-figure 506 shows four patterns with no spatial repetition in either the X or Y axis, exhibiting irregular structures. Sub-figure 508 presents four patterns that are periodic along the X axis only.

These examples demonstrate how a design clip's layout can exhibit different periodicities, and, accordingly, each clip can be binned into a category that reflects its dominant repetitive structure (or lack thereof).

In some cases, a design clip may include polygons that cross the field of view (FOV), which should be carefully processed to avoid incorrect labeling of a clip as non-periodic. FIG. 6 exemplifies this issue by comparing a cropped design clip with an uncropped version of the same clip when determining periodicity.

Specifically, FIG. 6 illustrates an example of a cropped design clip 602 and an uncropped design clip 604. In the cropped design clip 602, the vertical line structures appear truncated at both the left and right edges of the field of view (FOV). Because these lines are cut off, the design clip 602 seems to lack consistent repetition along the X axis, thus giving a misleading impression of non-periodicity. In contrast, the uncropped design clip 604 contains the complete polygons across the FOV. When the entire polygon geometry is visible, it becomes clear that these vertical lines repeat at regular intervals, indicating true periodicity along the X axis. By working with uncropped design data, the binning module 104 can ensure that each polygon is fully analyzed for repetition before determining a design clip as periodic or non-periodic.

By grouping design clips into bins based on their identified periodicity characteristics, the system can more effectively segregate design patterns that share similar repetitive structures. In subsequent stages (such as feature extraction, clustering, and sampling), this periodicity binning ensures that design clips with analogous geometric repetition are processed together, leading to more accurate clustering and sampling outcomes and improved coverage of design pattern variations in the training set.

Next, clustering and sampling are performed for each bin of the plurality of bins (206). Specifically, for each bin, feature vectors representing design patterns of the design clips in the bin can be extracted, and the design clips can then be clustered (208) (e.g., by the clustering module 106) to one or more clusters based on the feature vectors thereof.

The extracted feature vectors can be derived in a variety of ways. By way of example, the feature vectors can be of a type selected from a group comprising Fourier features, histogram of moments, histogram of oriented gradients (HOG), vertex-related function, and unique polygon counts.

By way of example, one type of feature vector suitable for capturing repetitive structures in design patterns are Fourier features, which represent the frequency-domain information of the design clip. An example of extracting Fourier features per layer of the design clip is described below.

A two-dimensional (2D) Fourier transform is applied to the rasterized image of a design clip, converting the spatial domain data into the frequency domain. The power spectrum is then obtained by taking the magnitude (norm) of the resulting Fourier coefficients. This power spectrum measures the intensity of each frequency component in the image and is especially useful for highlighting repetitive patterns. For instance, if a pattern repeats horizontally or vertically, it will exhibit strong peaks at corresponding frequency bins.

In some cases, the DC component (the zero-frequency term) can be omitted. This is because the DC component primarily reflects overall brightness or total pixel count, which can overshadow or bias the subsequent distance metrics. Omitting the DC component may prevent large uniform areas or differences in brightness from dominating the frequency-based comparison of patterns.

In some implementations, rather than retaining the entire 2D power spectrum, the system may reduce dimensionality by taking only a single slice, such as the x=0 or y=0 line in the Fourier domain. This step is particularly beneficial for “Manhattan”-style geometry (common in semiconductor layouts) and further simplifies the feature vector.

Each retained line (or slice) of the power spectrum is processed by calculating a cumulative sum across its frequency bins. This step is designed to ensure that frequencies that are close to each other map to feature values that are likewise close in the final vector. By adopting a cumulative sum, small shifts in frequency produce proportionally small changes in the feature representation.

The cumulative sum vector is then normalized so that its total sums to 1. This prevents the Euclidean distance metric from treating two equally “peaked” distributions differently simply because one is shifted by one bin. By contrast, if the vector is not normalized, the distance between, for example, [1 0 0 0 0] and [0 0 0 0 1] might be the same as the distance between [1 0 0 0 0] and [0 1 0 0 0]. Normalizing ensures the final feature representation better reflects differences in the overall shape of the distribution rather than raw amplitude.

In scenarios where a design clip spans multiple CAD layers, each layer can produce a separate Fourier feature vector. These vectors may then be concatenated to form a single composite feature vector for the entire clip, capturing the repetitive patterns present in each layer.

While Fourier features can be advantageous in some cases for identifying and measuring repetitive structures, the present disclosure is not limited to frequency-domain approaches. Additional feature types may include:
Histogram of Moments: Calculating spatial moments (e.g., raw moments, central moments) across the rasterized image to characterize shape properties.
Histogram of Oriented Gradients (HOG): Dividing the image into cells and aggregating the orientation of gradients in each cell, yielding a feature vector reflective of local edge structures.
Vertex-Related Function: Measuring how many polygon vertices fall within certain sub-regions or how polygon edges align within the field of view.
Unique Polygon Counts: Tracking the number of unique polygons or shapes in each design clip, providing a coarse measure of complexity or repetition.

Once these feature vectors are computed, they serve as the input to the clustering module 106, which partitions the design clips into clusters whose members share similar feature vectors. The goal is to ensure that each cluster represents a distinct category of design patterns, making subsequent selection steps more effective.

By way of example, the clustering can be performed using a variety of algorithms, such as K-means clustering, Gaussian Mixture Models (GMM), Dirichlet Process GMM (DPGMM), or Hierarchical Density-Based Spatial Clustering of Applications with Noise (HDBSCAN). For instance, K-means clustering requires the user to specify the desired number of clusters, k. This method partitions the dataset into k clusters by minimizing the sum of squared distances between points and their respective cluster centroids. Gaussian Mixture Models (GMM) view each cluster as a Gaussian distribution, allowing for soft assignment of design clips to multiple clusters with varying probabilities. Dirichlet Process GMM (DPGMM) extends GMM by using a non-parametric prior that lets the model infer the number of clusters from the data itself, rather than requiring a fixed k. HDBSCAN does not require specifying k in advance. Instead, it discovers clusters based on density thresholds and can automatically handle outliers or noise points. The present disclosure is not limited to the specific clustering algorithm used for performing the clustering.

In some cases, a practical challenge can be how to determine the number of clusters that best capture the variety of design patterns in a given bin. Certain standard model-selection methods (such as, e.g., silhouette scores, or the Davis-Bouldin index, etc.) may provide guidance but are often not robust enough for large, high-dimensional datasets, particularly those encountered in semiconductor design data. Consequently, it can be tedious and time-consuming for the user to identify the “correct” k that leads to satisfactory pattern clustering.

One approach to address this issue is to over-cluster, meaning that a relatively larger k is deliberately chosen to create more clusters than might be strictly necessary. The motivation or benefits behind this approach can be multi-fold. For instance, by picking a relatively large k, each cluster tends to become more homogeneous. Highly similar design clips end up grouped together, facilitating downstream tasks such as duplicate removal and sampling. In addition, over-clustering yields finer-grained clusters, where each cluster is smaller and more uniform. In such cases, sampling a few design clips from each cluster is more likely to yield coverage of that pattern's subtle variations, without excessively duplicating data from broader distributions.

In large semiconductor design datasets, many patterns are repeated frequently, but some are rarer or more complex. Over-clustering ensures that even these rare or intricate patterns form their own small clusters (or appear as outliers in density-based methods), rather than being lost in larger, more heterogeneous clusters. Consequently, the final sampling stage is more likely to include at least a few design clips representing less common patterns, improving the diversity and representativeness of the training set. Therefore, in some cases, k can be selected taking into consideration the over-clustering, the type of design patterns in each bin, and computation requirements, etc.

In some embodiments, the clustering in block 208 can be performed in a plurality of stages, with each stage applying a designated clustering algorithm (and potentially a distinct feature representation) to one or more output clusters produced by the preceding stage (except for the first stage where the designated clustering algorithm is applied to the entire bin).

An example of such a multi-stage clustering flow is described now. In the first stage, a first clustering algorithm—such as K-means—is applied to the entire set of design clips in a particular bin using a selected feature representation (e.g., Fourier-based feature vectors). This initial clustering partitions the design clips into a specified number of clusters, capturing broad distinctions among the design patterns. In the second stage, for each cluster produced at the first stage, a second clustering algorithm, and possibly a different set of features, can be selected (which may be the same as or different from the first). This algorithm is then applied within that cluster's subset of design clips, further subdividing it into smaller, more homogeneous sub-clusters.

Additional stages can be iteratively introduced, each applying its own algorithm and feature set to the sub-clusters formed in the preceding stage. The process continues until a predefined stopping criterion is reached, such as a maximum number of stages, a threshold for cluster homogeneity, or user-specified requirements for cluster size.

In large-scale data scenarios, the multi-stage clustering approach allows the system to first isolate broad distinctions at first stage 1 (e.g., separating fundamentally different design motifs), then refine the classification within each group at subsequent stages (e.g., addressing subtle variations). Each subsequent stage deals with smaller subsets, simplifying computational overhead and enabling deeper inspection of localized design pattern variations. By tailoring both the clustering method and the feature representation at each stage, the system can address specific design pattern complexities that might not be adequately captured in a single clustering pass.

Once the clusters are formed, a sampling step follows, to select a representative subset of clips within each cluster. Specifically, for each cluster, a subset of design clips can be sampled (212) (e.g., by the sampling module 108), which collectively span a full spectrum of unique design pattern variations present within the cluster.

In some embodiments, the sampling can comprise ranking the design clips in each cluster, and selecting, from among the ranked design clips, a subset of design clips.

By way of example, in one embodiment, the sampling can comprise ranking the design clips in each cluster with respect to a center of the cluster, and selecting, from among the ranked design clips, a subset of design clips that is evenly distributed in the feature space of the cluster.

By way of example, each cluster has a designated “center,” which may be, e.g., a centroid (in the case of K-means), or a mean/median vector if using other algorithms (e.g., GMM). The design clips within that cluster can be ranked by computing the distance between each clip's feature vector and the cluster center based on a distance metric. Common distance metrics that may be used include Euclidean distance, cosine distance, or Manhattan distance, etc., although the specific choice may vary based on the nature of the feature vectors. By sorting the clips from closest to farthest relative to the center, the system gains a gradient of how “typical” or “outlying” each design clip is within that cluster.

After ranking, the subset of clips can be selected in a manner that ensures an even distribution across the cluster's feature space. For instance, it is possible to pick clips at regular intervals from the sorted list (e.g., picking the 1st, 10th, 20th, etc., out of 100). This ensures that the final subset includes not only clips close to the cluster center, but also those near the periphery of the cluster, thereby capturing the full breadth of pattern variations.

It is to be noted that the term “evenly distributed” refers to a selection of design clips from a cluster that collectively span the entire range of variations in the feature space, ensuring that the clips cover the feature space without large gaps. This does not necessarily require that the distribution of clips be strictly even. In one particular embodiment, “evenly distributed” can be implemented as a uniform distribution, meaning that the selected design clips are spaced at approximately equal intervals according to a defined distance metric so that the distance between successive selected clips is constant. This approach guarantees that all regions of the feature space are represented with equal importance. However, the broader definition of “evenly distributed” permits sampling strategies that achieve balanced coverage without meeting the strict mathematical criteria of a uniform distribution.

In an alternative embodiment, the sampling can comprise ranking the design clips in each cluster using a diversity ranking algorithm, determining the number of design clips to be selected based on the ranking, and selecting, from among the ranked design clips, a subset of design clips in accordance with the determined number of design clips.

By way of example, the diversity ranking can apply a “farthest-point” or “loneliness” algorithm to maximize coverage of distinct design patterns. For instance, initially, for each design clip in the cluster, the system calculates its distance to every other clip in that set. For each clip, the closest distance to any other clip is identified—effectively the clip's “minimum neighbor distance.” The clip whose minimum neighbor distance is largest is deemed the most “lonely” or distinct item, and is therefore selected as the first clip.

After selecting the first “loneliest” clip, the algorithm updates each remaining unselected clip's distance to the already-selected set. Specifically, for every unselected clip, the distance to its nearest selected clip is computed. The clip whose nearest distance is greatest is chosen as the second clip, ensuring that each new selection is as “far” as possible from the previously selected group. This iteration continues so as to sequentially rank the design clips in the cluster.

The number of design clips to be selected can be determined based on the ranking. In some cases, an elbow plot can be used to determine the number of design clips to be selected. An example of an elbow plot is demonstrated below with reference to FIG. 8. Selecting a point near the elbow in the plot (where the slope levels off) can be beneficial for determining an optimal number of design clips to be selected, balancing thorough coverage of diverse design patterns against the overhead of adding more clips.

Once the number is determined, a subset of design clips can be selected from among the ranked design clips in accordance with the determined number.

In some cases, the above embodiments can be partially integrated. For instance, the design clips in each cluster can be ranked using the diversity ranking algorithm, and the number of design clips to be selected can be determined based on the ranking. Once the number is determined, a subset of design clips that is evenly distributed in the feature space of the cluster can be selected from among the ranked design clips.

Each cluster thus yields a final subset of design clips, which collectively reflect the unique design patterns in that cluster. Upon sampling, one or more subsets of design clips are obtained (one per cluster), corresponding to the one or more clusters in the bin, ensuring that every major grouping within the bin is adequately represented in the final sampling.

In some cases, optionally, prior to the sampling, a first duplicate removal can be performed (210) within each cluster, to eliminate design clips with duplicate design patterns. This step focuses on identifying and eliminating design clips that are duplicates (or near duplicates) of one another—i.e., clips that depict the same design pattern, or patterns that are nearly identical in geometry (e.g., in accordance with a similarity measure).

In some cases, duplicate removal can be performed by pattern matching in the spatial domain, e.g., by comparing the rasterized images of the design clips to identify near-identical design clips using a similarity measure (e.g., normalized cross-correlation). A similarity threshold can be set to govern when two design clips are considered “duplicates.” Clips that exceed this threshold are flagged, and the system can automatically remove one to avoid redundant representation.

Having said the above, duplicate removal can also be performed using alternative approaches, such as e.g., by comparing the feature vectors of the design clips using a suitable distance metric (e.g., Euclidean, cosine, or Manhattan distance). This approach evaluates the similarity of the extracted features directly, and if two design clips have feature vectors that are sufficiently close, one clip may be removed as a duplicate.

In cases where the first duplicate removal is performed, sampling of the subset of design clips described above will be performed on the remaining design clips (that are not eliminated during the first duplicate removal). By removing duplicate clips before the sampling step, it ensures that the diversity-based sampling is not overwhelmed by multiple copies of the same pattern, rendering the final subset to better reflect genuine variety in design patterns.

In some embodiments, optionally, after sampling has been conducted within each cluster, a second duplicate removal can be performed (214) across the sampled one or more subsets of design clips within each bin. The purpose of this second stage is to identify and remove redundant design clips that may have been sampled from different clusters, yet represent very similar or identical design patterns when viewed in the context of the overall bin. This second duplicate removal step can be executed in a similar manner to the first duplicate removal described above with respect to individual clusters, e.g., via pattern matching or other alternative methods.

Performing duplicate removal in two stages offers several technical benefits compared to a single, comprehensive duplicate removal at the bin level.

By first eliminating duplicates within each cluster (which contains a relatively small and homogeneous group of design clips), the system significantly reduces the number of items that need to be compared at the bin level in the second removal. This hierarchical approach limits the computational overhead associated with comparing a large, heterogeneous set of design clips, and improves computation efficiency.

In addition, the two-stage duplicate removal process helps preserve the diversity of design patterns by ensuring that not only are redundant samples within clusters removed, but also that overlaps between clusters are minimized. This results in a training set that more comprehensively spans the range of unique design pattern variations present in the original bin.

This hierarchical method is also more scalable for large datasets, as it breaks down a potentially cumbersome global duplicate removal task into smaller, manageable steps, leading to improved overall processing speed and resource utilization.

Upon the sampling or the second duplicate removal, the one or more subsets of design clips from each bin of the plurality of bins can collectively constitute a training set for training an ML model.

According to certain embodiments of the present disclosure, a portion of the one or more subsets of design clips can be further selected for registration, prior to being incorporated into the training set. This is intended to ensure that at least a portion of the design clips is verified (registered) with corresponding images (e.g., SEM images), thereby anchoring the training set with high-quality, verified data.

FIG. 3 illustrates a generalized flowchart of such further selection and registration in accordance with certain embodiments of the presently disclosed subject matter.

After the design clips in a bin have been clustered and sampled, one or more design clips can be selected (302) from the sampled one or more subsets of design clips for each bin. The number of design clips to be selected can be determined based on a predefined budget, such as resulting from an elbow-plot analysis, as exemplified in FIG. 8 below. For instance, if the elbow plot suggests that capturing 10 design clips per bin provides adequate coverage without excessive redundancy, the user might set that as the registration budget.

In some embodiments, the selection can be performed based on a diversity ranking in accordance with the budget. To maximize coverage of distinct design patterns, in some cases the diversity ranking can apply a “farthest-point” or “loneliness” algorithm. In this method, each design clip in the sampled subset is assigned a distance to the already-selected set. Initially, for each design clip, the system calculates its distance to every other clip in that set. For each clip, the closest distance to any other clip is identified—effectively the clip's “minimum neighbor distance.” The clip whose minimum neighbor distance is largest is deemed the most “lonely” or distinct item, and is therefore selected first.

After selecting the first “loneliest” clip, the algorithm updates each remaining unselected clip's distance to the already-selected set. Specifically, for every unselected clip, the distance to its nearest selected clip is computed. The clip whose nearest distance is greatest is chosen next, ensuring that each new selection is as “far” as possible from the previously selected group. This iteration continues until the user-defined budget (e.g., determined via elbow plot) is reached or another stopping criterion is met. In doing so, the algorithm ensures coverage of the broad range of pattern variations present in the bin's sampled set.

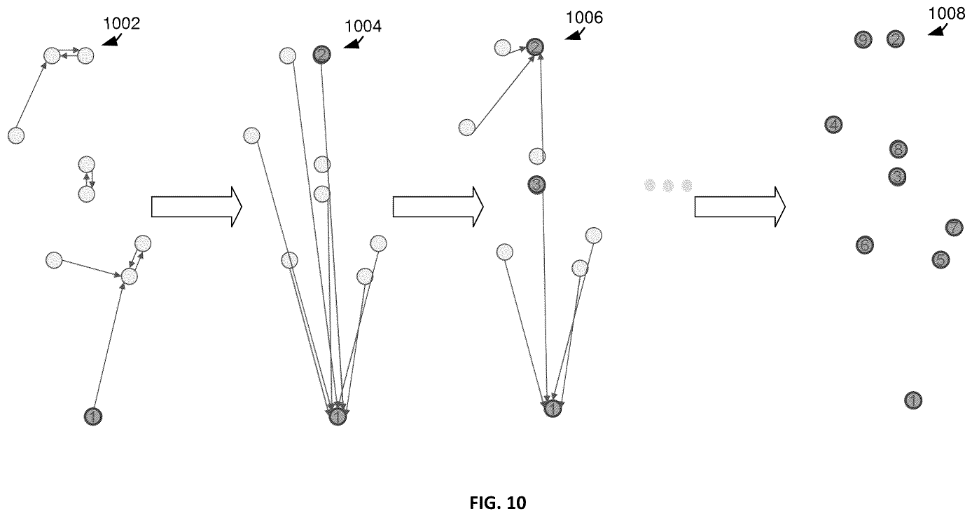

FIG. 10 illustrates an example of the diversity ranking process in accordance with certain embodiments of the presently disclosed subject matter.

In this figure, lighter circles (circles with lighter colors) represent unselected design clips, while darker circles (circles with darker colors, also labeled with numbers in the center of the circles) indicate the clips that have been selected at each iteration. The goal is to choose clips that are “most lonely,” or, in other words, have the largest minimum distance to any already-selected clip. By successively picking the most lonely clip, the algorithm ensures that the final selected set spans the broad range of pattern variations within the bin.

In the initial state (1002), all design clips are initially unselected. The system computes, for each clip, its distance to every other clip in the unselected set and identifies the minimum neighbor distance of each clip (i.e., how close it is to its nearest clip). The clip whose minimum neighbor distance is largest is the “most lonely” item. In the example of FIG. 10, that item is selected first, labeled as 1 (representing clip 1), and the circle turns darker for purpose of illustration.

In the next iteration (1004), the system updates, for each unselected clip, its distance to each of the selected clips, and the nearest distance among those selected clips. The unselected clip whose nearest distance to the selected set is largest is now deemed the “most lonely” among the remaining items. In 1004, the second circle is chosen (labeled as 2) based on this criterion, reflecting that it is farthest from circle 1 (clip 1) in terms of its feature-space distance. Arrows or lines may be shown in the figure to visualize how the nearest distances are determined.

The system continues this process for subsequent iterations. Each time a clip is selected, the circle turns darker, and the system updates every unselected clip's “distance to the selected set” by finding the smallest distance to any already-selected clip. In 1006, another circle (labeled as 3) is chosen. As more darker circles appear, they represent newly added design clips that are farthest from the existing selected set.

The selection process repeats until a predefined stopping criterion is reached, such as a user-defined budget (e.g., from an elbow plot). In 1008, the final set of darker circles represents the chosen design clips that collectively cover the cluster's feature-space distribution. Because each newly added clip was farthest from any selected clip, the final set effectively includes diverse design patterns, including both typical and outlying variations.

FIG. 8 illustrates an example of an elbow plot in accordance with certain embodiments of the presently disclosed subject matter.

An elbow plot refers to a line chart which can be used to identify a “sweet spot” or stopping criterion in various selection processes. In the context of the present disclosure, an elbow plot can guide the user in determining how many design clips to select (from the sampled subsets in a bin) in order to capture sufficient diversity without excessively increasing the total number of samples.

As shown in the figure, the x-axis represents the number of design clips selected so far in a farthest-point or other diversity-based sampling procedure. The y-axis represents the “minimum neighbor distance” as calculated for each selected design clip.

The plot generally starts at a higher value on the y-axis (e.g., large distance) and decreases as more samples are included. The line descends relatively steeply at first, indicating that each additional clip yields a substantial improvement in coverage. Eventually, the slope levels off, forming an “elbow”—a transition zone where the rate of improvement diminishes markedly. This elbow indicates that beyond a certain number of samples, adding more design clips confers only a marginal benefit. Selecting a point near this elbow is useful for determining an optimal or near-optimal budget for sampling, balancing thorough coverage of diverse design patterns against the overhead of adding more samples.

In the context of the present disclosure, the elbow plot helps decide how many design clips should be chosen for registration. For instance, it can be observed in FIG. 8 that the plot has a pronounced elbow around clips 7-10 at the x-axis (as marked by dashed lines in the figure), meaning that going beyond that many samples yields only minor gains in diversity. The exact location of the elbow point can be flexible, depending on practical constraints such as e.g., time and resources available for registration, etc. By picking the elbow point as the budget for design clip selection, the user ensures that the selected design clips adequately span the variation in the bin's patterns for registration.

Referring back to FIG. 3, after selecting one or more design clips (e.g., using diversity ranking and an elbow-based budget) from each bin, those clips proceed to a registration step (304) with one or more corresponding images (e.g., SEM images, optical images, or other inspection outputs), forming one or more registered pairs of design clips and images.

The images corresponding to the design clips can refer to actual images acquired by an examination tool, such as a scanning electron microscope (SEM), optical microscope, or others, from a physical training specimen or wafer. As each selected design clip is associated with a specific location on the wafer, defined by the underlying design data, the corresponding image captures the actual wafer patterns at that same location.

Registration typically involves matching the coordinate system of the design clip to the coordinate system of the image so that the image is aligned with the design clip's geometry. This alignment may be manual (i.e., user-driven) or automated.

In certain embodiments, the registration process can be performed at various levels of precision, depending on the user's needs, the performance requirements, and the capabilities of the system. For instance, some applications only require a coarse registration, in which the design clip is aligned to its corresponding image by applying a global shift or scale adjustment to approximate the clip's position on the wafer and match the approximate field of view. This coarse alignment might rely on bounding box coordinates or a minimal set of reference points, ensuring a basic overlay that suffices for higher-level tasks (e.g., verifying that the clip indeed corresponds to the right die or wafer region).

In contrast, other embodiments may employ a more rigid registration, where transformations such as rotation, translation, or scaling are applied to achieve a more precise match between the design clip and the actual image. This rigid alignment can incorporate advanced image-processing algorithms or user-driven landmark selection to refine the fit.

In either case, once the registration is complete, the design clip and its aligned image form a registered pair that explicitly links the abstract design pattern with its actual observed manifestation on the wafer. The one or more registered pairs of design clips and images can be included (306) in the training set.

Because each design clip has been verified to match a specific location in the wafer image, the ML model can directly learn the correspondence between abstract design data and the real-world visual characteristics. This is especially beneficial in cases where the ML model aims to generate simulated images or detect defects by comparing design patterns with inspection images.

Registered pairs serve as robust reference examples that help the model generalize to unseen patterns. They provide clear “ground truth” data, reducing model drift or confusion that might arise if only unlabeled or unverified design clips were used.

In parallel, the remaining design clips from the sampled subsets of design clips, which have not undergone registration, are incorporated directly into the training set along with their corresponding images (308). These unregistered clips are simply paired with their corresponding images at the same wafer coordinates, but no additional alignment or registration step is performed.

The combination of the registered pairs with unregistered clips yields a training dataset that is semi-supervised. In such a semi-supervised approach, the registered pairs provide reliable, labeled examples, while the unregistered clips expand the dataset to cover a broader range of design patterns. This dual inclusion enables the ML model to learn from both high-quality, verified data and a larger, more diverse set of examples, thereby enhancing generalization and robustness.

This semi-supervised approach also keeps registration tasks manageable. The system can invest the most effort only in verifying/registering those clips deemed essential (e.g., by a budget or elbow-plot analysis), while automatically including all other sampled clips for breadth. Such dual-level data integration is more efficient and scalable than fully verifying every single design clip.

The training set as obtained can be used to train a ML model usable for various applications in semiconductor examination. By way of example, in one embodiment the ML model can be configured for design-based image simulation.

In some embodiments, the ML model can be trained in two sequential stages to leverage the strengths of both high-confidence registered data and the broader, diverse unregistered data. Initially, the model is trained in a supervised manner using only the registered pairs—each comprising a design clip and its corresponding, accurately aligned image obtained through either coarse or rigid registration. This initial phase provides a robust foundation, as the model learns from verified and high-quality examples that accurately represent the intended design patterns.

Once the model has been well-initialized, a subsequent semi-supervised training phase is conducted where the unregistered pairs, representing a larger and more diverse set of design clips, are incorporated. During this phase, the model is further fine-tuned, enabling it to generalize more effectively across a wide range of design pattern variations present in semiconductor specimens.

This two-stage training approach, where high-quality supervised data anchors the learning process, followed by the inclusion of additional unlabeled or weakly labeled data, enhances overall model performance and robustness in defect detection and simulation tasks.

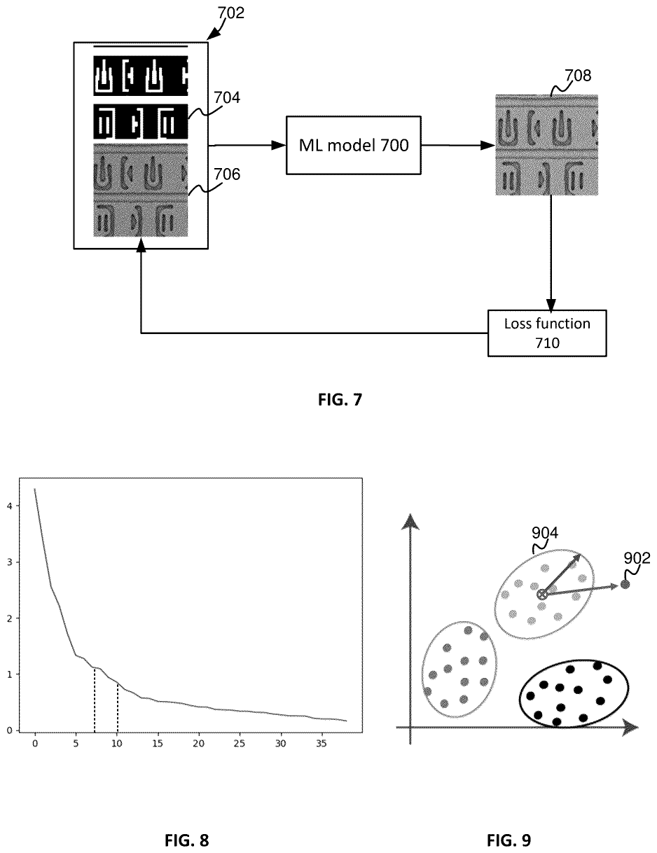

FIG. 7 shows a schematic illustration of the supervised training phase for the ML model in accordance with certain embodiments of the presently disclosed subject matter.

As shown, a registered pair 702 is provided, comprising a design clip 704 (or the rasterized image thereof) and a corresponding actual image 706. This training pair 702 is input into the ML model 700. The ML model 700 is designed to perform image simulation, translating representations from the design space to realistic wafer images that mimic the actual image 706. Upon receiving the design clip 704, the ML model 700 generates a simulated image 708 that aims to replicate the visual characteristics of the actual image 706. The simulated image captures the geometric transformations and imaging domain characteristics observed in real SEM (or other imaging modality) outputs.

To optimize the ML model, a loss function 710 measures the difference between the simulated image 708 and the actual image 706. This loss function provides feedback to the ML model, guiding it to iteratively improve its predictions and synthesize highly realistic wafer images. For instance, the loss function may take the form of a mean absolute error (L1), mean squared error (L2), perceptual loss, adversarial loss (if using a GAN setup), or any suitable measure of similarity. By minimizing this difference, the ML model learns to synthesize highly realistic wafer images from the design clip.

When using the unregistered pairs to train the ML model 700 in the second stage, the loss function 710 can incorporate one or more semi-supervised or unsupervised objectives that do not rely on pixel-level registration. In one embodiment, a geometric consistency loss can be applied: the model's simulated output for an unregistered design clip is compared not only to the unaligned real image, but also to transformed versions of that image (e.g., translated or rotated back into the clip's frame). By penalizing discrepancies in shape, position, and structural features across these transformations, the geometric consistency loss encourages the network to preserve the correct object geometry, even when exact registration is unavailable.

In another embodiment, an adversarial loss can be incorporated when using a GAN setup, e.g., by coupling the simulation network (the generator network) with a discriminator network that learns to distinguish real SEM images from the model's outputs. The simulation network is penalized whenever the discriminator correctly identifies a simulated image, thereby pushing the generator toward producing more realistic textures and fine details.

In some cases, these two losses may be possibly combined (e.g., via a weighted sum) and optionally augmented with additional terms—such as, e.g., a perceptual loss, to guide the model toward plausible, high-quality simulations when trained on the broader, diverse set of unregistered pairs.

Having described the setup phase where the training set has been generated and the ML model has been trained, reference is now made to FIG. 4, illustrating a generalized flowchart of a runtime monitoring process of design patterns in accordance with certain embodiments of the presently disclosed subject matter. FIG. 4 reflects how a new design clip is handled in runtime after the setup phase has established bins, clusters, and ML models, etc.

During runtime, a newly encountered design clip is obtained (402) and provided to the system (e.g., system 101 when serving as a runtime monitoring system). This design clip represents a design pattern of a semiconductor specimen to be examined in runtime. The design clip may be derived from various sources—for example, a new wafer under inspection, a newly detected potential defect site, or an updated region of interest.

The system references the periodicity binning criteria established in the setup phase (e.g., whether a clip is periodic along the X axis, Y axis, both, or none). The new clip can be assigned (404) to the appropriate bin of the plurality of bins established during setup, based on one or more periodicity characteristics of the design pattern. For instance, the design pattern in the design clip can be evaluated for periodic repetition along one or more directions of the X axis, Y axis, both X and Y axes, an oblique direction relative to X or Y axis, or absence of periodic repetition in any direction. This ensures that the clip is compared only against previously formed clusters that share the same or similar periodicity characteristics, improving the reliability of subsequent analysis steps.

Once binned, a feature vector can be extracted (406) for the new clip. This process can be typically performed in a similar manner as the feature extraction used in the setup phase, such as Fourier-based features or other metrics. By applying the same method used during setup, the runtime system ensures that the new clip's feature vector is directly comparable to the feature vectors of the design clips used to train the ML model.

Within the assigned bin, one or more clusters (as well as their cluster centers) exist from the setup phase. The new design clip can be assigned (408) to a cluster of the one or more clusters in the bin, based on its feature vector. For instance, the monitoring system can compare the feature vector of the new clip to the one or more cluster centers of the one or more clusters, by calculating the distance between the feature vector and the centers of these clusters. Various distance metrics can be used (e.g., Euclidean, cosine, or Manhattan distance) for calculating the distance, as described above. The new clip can be then assigned to the cluster whose cluster center is closest to the feature vector (i.e., whose center yields the smallest distance). This step effectively determines which existing cluster best represents the design pattern of the new clip, leveraging the previously established categorization of design clips.

Having assigned the clip to a cluster, the monitoring system computes (410) an anomaly score based on the distance between the new clip's feature vector and that cluster's center. The anomaly score is indicative of a degree of deviation of the new design clip from a set of representative design clips previously included in a training set during a setup phase.

By way of example, if the clip's feature vector is close to the cluster center, the anomaly score will be relatively low, indicating that the new clip's design pattern is well-represented by the existing training data. Conversely, if the clip is far from the cluster center, the anomaly score increases, suggesting that the clip exhibits features insufficiently covered in the training set.

The system compares (412) the anomaly score against a predetermined threshold. If the anomaly score exceeds this threshold, it indicates that the new clip is substantially different from the design patterns captured during the setup phase. In other words, the clip may represent a novel or insufficiently represented pattern. The threshold may be user-defined or dynamically determined (e.g., based on statistical distribution of distances observed in the training data).

FIG. 9 illustrates an example of a new design clip and its anomaly determination in accordance with certain embodiments of the presently disclosed subject matter.

In FIG. 9, three clusters are shown in feature space, each represented by an elliptical boundary (for illustration) around its cluster center. The cluster 904 has a center (marked with a cross), and a new design clip 902 is depicted at some distance from that center. The distance between clip 902 and the cluster center can be computed using a chosen distance metric, e.g., Euclidean distance in the feature space.

During the setup phase, each of the three clusters is formed by grouping design clips with similar feature vectors. The setup system may record a “cluster radius” or boundary, derived from statistics of the cluster's members (for example, the maximum or average distance from the center to the cluster edges). This radius helps approximate the extent of patterns considered “normal” or well-represented within that cluster.

To provide a flexible margin beyond the cluster boundary, in some cases it is possible to multiply the cluster radius by a factor (such as, e.g., 1.2, 1.5, etc.) to define the threshold for anomaly detection. For instance, this threshold can be represented conceptually as a circle or ellipse with a larger radius around the cluster center than the original cluster boundary.

By using a factor like 1.5, the monitoring system is less strict than if it uses the cluster boundary alone. This “extra room” accounts for potential variations that still resemble the cluster's patterns, but might lie just beyond the nominal cluster radius. It can avoid overly rigid classification, thus preventing false positives for clips that are only marginally different from the cluster's known patterns.

In the example of FIG. 9, the design clip 902's distance to the cluster center is measured. If this distance exceeds the threshold (i.e., the cluster radius multiplied by the chosen factor), clip 902 is flagged as an anomaly. Conversely, if the distance is within that threshold, the clip 902 is considered adequately represented by the cluster, and is not treated as being anomalous.

Continuing with FIG. 4, if the anomaly score is above the threshold, the system generates (414) an alert. This alert notifies the operator or another automated process/system that a new design pattern may be missing from the training set.

When the anomaly score indicates that the new design clip may lie outside the model's known distribution of design patterns, the ML model's simulated image for that clip might be inaccurate or misleading, thus possibly causing erroneous or incomplete inspection results that could arise from using a model's simulation in an uncharted region of design space. In such cases, the monitoring system may trigger additional actions, such as instructing the examination tool to acquire an actual (e.g., SEM) image instead of using the ML model to perform image simulation based on the new design clip.

Some additional actions may include prompting a retraining (at least partially) of the ML model to incorporate this newly discovered pattern in the training set. For instance, the training set can be updated to include the new design clip and a corresponding image, and the updated training set can be used to re-train the ML model.

If the anomaly score does not exceed the threshold, the system deems the new clip to be adequately represented by the existing training data. In this scenario, the new clip can be processed (416) using the ML model to generate a simulated image, such as the ML model 700 exemplified in FIG. 7, or to perform other inspection-related tasks (e.g., defect detection or classification).

It is also possible to update the cluster centers if the new design clip is accepted into an existing cluster. For instance, once the clip is deemed non-anomalous or otherwise confirmed to belong in that cluster, the system may choose to recalculate the cluster's centroid or representative point by including the new clip's feature vector in the averaging (or other centroid-defining) process. This incremental adjustment helps the cluster remain an accurate reflection of the design patterns it represents, particularly when new clips reveal subtle shifts or expansions in the cluster's feature space distribution.

The runtime monitoring process as described above with reference to FIG. 4 enables that new design clips are rapidly binned, cluster-assigned, and anomaly-scored, leading either to alerts for out-of-distribution patterns, or to direct processing by the trained ML model for simulation and defect detection. Reusing the bins, clusters, and feature extraction approach from the setup phase guarantees that new clips are assessed under the same criteria as the training data, promoting consistency and reliability.

It is to be noted that examples illustrated in the present disclosure, such as, e.g., the exemplified design and image representations, the exemplified ML models, the feature vectors, and the specific ranking algorithms, etc., are illustrated for exemplary purposes, and should not be regarded as limiting the present disclosure in any way. Other appropriate examples/implementations can be used in addition to, or in lieu of the above.

Among the advantages of certain embodiments of the presently disclosed subject matter as described herein, is streamlined data preparation for simulation-based ML training. Because design clips are sampled in a systematic, automated manner, rather than relying on manual user selection, it can drastically reduce the time-to-recipe associated with building a high-quality training set. This acceleration in data preparation enables faster deployment of simulation models and speeds up iterative refinement cycles in semiconductor inspection and analysis.

Among further advantages of certain embodiments of the presently disclosed subject matter as described herein, is improved coverage of design patterns, while minimizing user verification burden. By employing periodicity binning, clustering, optional duplicate removal, and sampling based on diversity ranking, the system ensures that a wide variety of design patterns is captured in the training set without requiring the user to painstakingly identify each pattern manually. This alleviates one of the primary challenges in current approaches, where incomplete coverage of patterns can result in sub-optimal model performance.

In particular, one specific technical advantage in this aspect relates to enhanced organization of design data through periodicity binning. By grouping design clips based on their periodic repetition characteristics, whether along the X axis, Y axis, oblique directions, or the absence of repetition, the system effectively segregates patterns that share similar geometric properties. This targeted grouping facilitates more accurate and efficient subsequent processing steps, enabling the system to focus on specific subsets of design patterns and reducing the overall computational complexity when dealing with vast amounts of semiconductor design data.

Among further advantages of certain embodiments of the presently disclosed subject matter as described herein, is the diversity-based sampling of design clips, which ensures that the final training set covers a broad spectrum of design pattern variations. By prioritizing “lonely” or outlier clips in the selection process, this method prevents the training set from becoming dominated by common, repetitive patterns, and instead captures the rare or less frequent geometries that may be critical for robust defect detection. As a result, the ML model benefits from a more comprehensive representation of the semiconductor design space, leading to improved accuracy and reliability when the model encounters unfamiliar or evolving layouts during production.

Among further advantages of certain embodiments of the presently disclosed subject matter as described herein, is the two-stage duplicate removal process. First removing duplicates at the cluster level, then performing a second removal across clusters within a bin, significantly reduces computational overhead and improves precision. By eliminating near-identical clips early on, in smaller, more homogeneous groups, the system avoids unnecessary pairwise comparisons on a larger scale. The subsequent, bin-level pass then removes any remaining overlaps among the sampled subsets, ensuring that the final training set is free of redundant design clips, yet still retains a rich diversity of patterns. This hierarchical approach yields a more efficient and accurate curation of data, compared to a single, comprehensive duplicate removal step.

Among further advantages of certain embodiments of the presently disclosed subject matter is the integrated anomaly detection for previously unseen design patterns. In the runtime phase, the system monitors new design clips to determine whether they are significantly different from the patterns used to train the ML model. If the system detects an anomaly, it can proactively prompt the acquisition of real images for further investigation, and optionally update the training set to incorporate the new pattern. This mechanism helps maintain model robustness over time as the semiconductor process evolves or new design variations emerge.

Among further advantages of certain embodiments of the presently disclosed subject matter as described herein, is semi-supervised integration of unregistered design clips. Only a portion of the sampled clips needs to be registered with their corresponding images, while the rest are automatically included in the training set. This dual-level approach balances the need for high-quality, fully verified data with the desire for broad coverage of patterns, substantially reducing registration overhead without compromising the model's accuracy or adaptability.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “training”, “using”, “generating”, “grouping”, “extracting”, “clustering”, “sampling”, “ranking”, “selecting”, “performing”, “selecting”, “registering”, “including”, “incorporating”, “monitoring”, “assigning”, “computing”, “updating”, “instructing”, “processing”, “comparing” or the like, refer to the action(s) and/or process(es) of a computer that manipulate and/or transform data into other data, said data represented as physical, such as electronic, quantities and/or said data representing the physical objects.

The terms “computer”, “computer-based system” or “computerized system” should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the CAD sampling system, the runtime monitoring system, and respective parts thereof disclosed in the present application. The data processing circuitry (designated also as processing circuitry) can comprise, for example, one or more processors operatively connected to computer memory, loaded with executable instructions for executing operations. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application-specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates, including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limited to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as a “false alarm” defect) which can be disregarded because it has no effect on the functionality of the completed device and does not impact yield.

The term “defect candidate” used in this specification should be expansively construed to cover a suspected defect location on the specimen which is detected to have a relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computer-implemented method of generating a training set for training a machine learning (ML) model, the method comprising:
obtaining a set of design clips representing a set of design patterns of a semiconductor specimen;
grouping the set of design clips into a plurality of bins based on one or more periodicity characteristics of the set of design patterns;
for each bin of the plurality of bins:
extracting feature vectors representing design patterns of design clips in the bin, and clustering the design clips to one or more clusters based on the feature vectors thereof; and
for each cluster, sampling a subset of design clips that collectively span a full spectrum of unique design pattern variations present within the cluster, giving rise to one or more subsets of design clips corresponding to the one or more clusters in the bin;
wherein the one or more subsets of design clips for each bin of the plurality of bins constitute a training set for training the ML model.

2. The method according to claim 1, wherein the set of design clips corresponds to a set of locations of interest on the semiconductor specimen resulting from a preceding inspection process.

3. The method according to claim 1, wherein the one or more periodicity characteristics of the design patterns indicate periodic repetition of design elements along one or more directions of X axis, Y axis, both X and Y axes, an oblique direction relative to X or Y axis, or absence of periodic repetition in any direction.

4. The method according to claim 1, wherein the extracted feature vectors are of a type selected from a group comprising Fourier features, histogram of moments, histogram of oriented gradients (HOG), vertex-related function, and unique polygon counts.

5. The method according to claim 1, wherein the clustering is performed using a clustering algorithm selected from a group comprising: K-means clustering, Gaussian Mixture Models (GMM), Dirichlet Process GMM (DPGMM), and Hierarchical Density-Based Spatial Clustering of Applications with Noise (HDBSCAN).

6. The method according to claim 1, wherein the clustering is performed in a plurality of stages, with each stage applying a designated clustering algorithm to one or more resulting clusters from a preceding stage.

7. The method according to claim 1, wherein the sampling comprises ranking design clips in the cluster with respect to a center of the cluster, and selecting, from among the ranked design clips, a subset of design clips that is evenly distributed across a feature space of the cluster.

8. The method according to claim 7, further comprising, prior to the sampling, performing first duplicate removal within each cluster to eliminate design clips with duplicate design patterns, and wherein the ranking is performed on remaining design clips after the first duplicate removal.

9. The method according to claim 1, further comprising performing second duplicate removal across the sampled one or more subsets of design clips within each bin.

10. The method according to claim 1, further comprising:
selecting one or more design clips from the sampled one or more subsets of design clips for each bin;
registering the one or more design clips with one or more corresponding images to form one or more registered pairs of design clips and images;
including the one or more registered pairs of design clips and images in the training set; and
incorporating remaining design clips from the sampled one or more subsets of design clips and corresponding images directly into the training set without registration.

11. The method according to claim 10, wherein the selection of the one or more design clips is based on diversity ranking in accordance with a predefined budget.

12. The method according to claim 1, wherein the training set is used to train the ML model configured to perform image simulation based on design data.

13. A computerized system for runtime monitoring of design patterns in a semiconductor specimen, the system comprising a processing circuitry configured to:
obtain, during runtime, a new design clip representing a design pattern of the semiconductor specimen;
assign the new design clip into one bin of a plurality of bins based on one or more periodicity characteristics of the design pattern;
extract a feature vector representing the design pattern;
assign the new design clip to a cluster of one or more clusters in the bin based on the feature vector; and
compute an anomaly score for the new design clip based on a distance between the feature vector and a center of the cluster, wherein the anomaly score is indicative of a degree of deviation of the new design clip from a set of representative design clips previously included in a training set during a setup phase.

14. The computerized system according to claim 13, wherein the processing circuitry is further configured to generate an alert if the anomaly score exceeds a predetermined threshold, thereby indicating that the design pattern in the new design clip is insufficiently represented in the training set.

15. The computerized system according to claim 14, wherein the training set is updated to include the new design clip and a corresponding image, and the updated training set is usable to re-train a machine learning (ML) model which is previously trained for image simulation during the setup phase using the training set.

16. The computerized system according to claim 14, wherein the processing circuitry is further configured to instruct the examination tool to acquire an actual image instead of performing image simulation based on the new design clip using a machine learning (ML) model previously trained during the setup phase using the training set.

17. The computerized system according to claim 13, wherein in cases where the anomaly score does not exceed a predetermined threshold, the processing circuitry is further configured to process the new design clip using a machine learning (ML) model, to generate a simulated image, wherein the ML model is previously trained for image simulation during the setup phase using the training set.

18. The computerized system according to claim 13, wherein the plurality of bins is generated during the setup phase, and the one or more periodicity characteristics indicate periodic repetition of design elements along one or more directions of X axis, Y axis, both X and Y axes, an oblique direction relative to X or Y axis, or absence of periodic repetition in any direction.

19. The computerized system according to claim 13, wherein the one or more clusters and one or more cluster centers thereof in each bin are generated during the setup phase, and the new design clip is assigned by comparing the feature vector to the one or more cluster centers of the one or more clusters, and assigning the new design clip to a cluster whose cluster center is closest to the feature vector.

20. A non-transitory computer-readable storage medium tangibly embodying a program of instructions that, when executed by a computer, cause the computer to perform a method of runtime monitoring of design patterns in a semiconductor specimen, the method comprising:
obtaining, during runtime, a new design clip representing a design pattern of the semiconductor specimen;
assigning the new design clip into one bin of a plurality of bins based on one or more periodicity characteristics of the design pattern;
extracting a feature vector representing the design pattern;
assigning the new design clip to a cluster of one or more clusters in the bin based on the feature vector; and
computing an anomaly score for the new design clip based on a distance between the feature vector and a center of the cluster, wherein the anomaly score is indicative of a degree of deviation of the new design clip from a set of representative design clips previously included in a training set during a setup phase.
